(19) United States
(12) Patent Application Publication
(10) Pub. No.: US 2010/0224240 A1
(43) Pub. Date: Sep. 9, 2010

(54) COUNTERDOPING FOR SOLAR CELLS

(75) Inventors: Nicholas BATEMAN, Reading, MA (US); Atul GUPTA, Beverly, MA (US); Paul SULLIVAN, Wenham, MA (US)

Correspondence Address: Nields, Lemack & Frame, LLC, 176 E. MAIN STREET, SUITE 5, WESTBOROUGH, MA, 01581, US

(73) Assignee: VARIAN SEMICONDUCTOR EQUIPMENT ASSOCIATES, INC., Gloucester, MA (US)

(21) Appl. No.: 12/781,406

(22) Filed: May 17, 2010

Related U.S. Application Data
(63) Continuation of application No. 12/397,646, filed on Mar. 4, 2009.
(60) Provisional application No. 61/033,873, filed on Mar. 5, 2008.
(60) Provisional application No. 61/074,278, filed on Jun. 20, 2008.
(60) Provisional application No. 61/096,378, filed on Sep. 12, 2008.

(51) Int. Cl. H01L 27/142

(52) U.S. Cl. 136/255; 257/E27.124

(57) ABSTRACT

Methods of counterdoping a solar cell, particularly an IBC solar cell are disclosed. One surface of a solar cell may require portions to be n-doped, while other portions are p-doped. Traditionally, a plurality of lithography and doping steps are required to achieve this desired configuration. In contrast, one lithography step can be eliminated by the use of a blanket doping of one conductivity and a mask patterned counterdoping process of the opposite conductivity. The areas dosed during the masked patterned doping receive a sufficient dose so as to completely reverse the effect of the blanket doping and achieve a conductivity that is opposite the blanket doping. In another embodiment, the counterdoping is performed by means of a direct patterning technique, thereby eliminating the remaining lithography step. Various methods of direct counterdoping processes are disclosed.

This application is a continuation of U.S. patent application Ser. No. 12/397,646, filed Mar. 4, 2009, which claims priority of U.S. Provisional Patent Application Ser. No. 61/033,873, filed Mar. 5, 2008, U.S. Provisional Patent Application Ser. No. 61/074,278, filed Jun. 20, 2008, and U.S. Provisional Patent Application Ser. No. 61/096,378, filed Sep. 12, 2008, the disclosures of which are hereby incorporated by reference.

### FIELD

This invention relates to doping solar cells, and, more particularly, to counterdoping a solar cell.

### BACKGROUND

Ion implantation is a standard technique for introducing conductivity-altering impurities into semiconductor substrates. A desired impurity material is ionized in an ion source, the ions are accelerated to form an ion beam of prescribed energy, and the ion beam is directed at the surface of the substrate. The energetic ions in the beam penetrate into the bulk of the semiconductor material and are embedded into the crystalline lattice of the semiconductor material to form a region of desired conductivity.

Solar cells are typically manufactured using the same processes used for other semiconductor devices, often using silicon as the substrate material. A semiconductor solar cell is a simple device having an in-built electric field that separates the charge carriers generated through the absorption of photons in the semiconductor material. This electric field is typically created through the formation of a p-n junction (diode), which is created by differential doping of the semiconductor material. Doping a part of the semiconductor substrate (e.g. surface region) with impurities of opposite polarity forms a p-n junction that may be used as a photovoltaic device converting light into electricity.

FIG. 9 shows a first embodiment of a solar cell, and is a cross section of a representative substrate 150. Photons 160 enter the solar cell 150 through the top surface 162, as signified by the arrows. These photons pass through an anti-reflective coating 152, designed to maximize the number of photons that penetrate the substrate 150 and minimize those that are reflected away from the substrate.

Internally, the substrate 150 is formed so as to have a p-n junction 170. This junction is shown as being substantially parallel to the top surface 162 of the substrate 150 although there are other implementations where the junction may not be parallel to the surface. The solar cell is fabricated such that the photons enter the substrate through a heavily doped region, also known as the emitter 153. In some embodiments, the emitter 153 may be an n-type doped region, while in other embodiments, the emitter may be a p-type doped region. The photons with sufficient energy (above the bandgap of the semiconductor) are able to promote an electron within the semiconductor material's valence band to the conduction band. Associated with this free electron is a corresponding positively charged hole in the valence band. In order to generate a photocurrent that can drive an external load, these electron hole (e-h) pairs need to be separated. This is done through the built-in electric field at the p-n junction. Thus any e-h pairs that are generated in the depletion region of the p-n junction get separated, as are any other minority carriers that diffuse to the depletion region of the device. Since a majority of the incident photons are absorbed in near surface regions of the device, the minority carriers generated in the emitter need to diffuse across the depth of the emitter to reach the depletion region and get swept across to the other side. Thus to maximize the collection of photo-generated current and minimize the chances of carrier recombination in the emitter, it is preferable to have the emitter region 153 be very shallow.

Some photons pass through the emitter region 153 and enter the base 154. In the scenario where the emitter 153 is an n-type region, the base 154 is a p-type doped region. These photons can then excite electrons within the base 154, which are free to move into the emitter region 153, while the associated holes remain in the base 154. Alternatively, in the case where the emitter 153 is a p-type doped region, the base is an n-type doped region. In this case, these photons can then excite electrons within the base 154, which remain in the base region 154, while the associated holes move into the emitter 153. As a result of the charge separation caused by the presence of this p-n junction, the extra carriers (electrons and holes) generated by the photons can then be used to drive an external load to complete the circuit.

By externally connecting the emitter region 153 to the base 154 through an external load, it is possible to conduct current and therefore provide power. To achieve this, contacts 151,155, typically metallic, are placed on the outer surface of the emitter region and the base, respectively. Since the base does not receive the photons directly, typically its contact 155 is placed along the entire cuter surface. In contrast, the outer surface of the emitter region receives photons and therefore cannot be completely covered with contacts. However, if the electrons have to travel great distances to the contact, the series resistance of the cell increases, which lowers the power output. In an attempt to balance these two considerations (the distance that the free electrons must travel to the contact, and the amount of exposed emitter surface 163) most applications use contacts 151 that are in the form of fingers.

The embodiment shown in FIG. 9 requires contacts on both sides of the substrate, thereby reducing the available area of the front surface through which photons may pass. A cross section of a second embodiment of a solar cell 100 is shown in FIG. 1. Fundamentally, the physics of this embodiment is similar, in which a p-n junction is used to create an electric field which separates the generated electron hole pairs. However, rather than create the p-n junction across the entire substrate, as done in the previous embodiment, the junctions are only created in portions of the substrate 100. In this embodiment, a negatively doped silicon substrate 103 may be used. In certain embodiments, a more negatively biased front surface field (FSF) 102 is created by introducing addition n-type dopants in the front surface. This front surface is then coated with an anti-reflective material 101. This front surface is often etched to create a sawtooth or other non-planar surface, so as to increase surface area. The metallic contacts or fingers 107,108 are all located on the bottom surface of the substrate. Certain portions of the bottom surface are doped with p-type dopants to create emitters 104. Other portions are doped with n-type dopants to create more negatively biased back surface field 105. The back surface is coated with a dielectric layer 460 to enhance the reflectivity of the back surface. Contacts 107 are attached to the emitter 104 and contacts 108 attach to the BSF 105. FIG. 10 shows one commonly used configuration of the contacts on the back surface. This type of cell is known as an interdigitated back contact (IBC) solar cell.

With current energy costs and environmental concerns, solar cells are becoming more important globally. Any reduced cost to the manufacturing or production of high-performance solar cells or any efficiency improvement to high-performance solar cells would have a positive impact on the implementation of solar cells worldwide. This will enable the wider availability of this clean energy technology.

The current manufacturing process for interdigitated back (or backside) contact solar cells requires at least two lithography and diffusion steps on the backside of the solar cell to fabricate the contact and emitter regions. Removing any process steps would reduce the manufacturing costs and complexity for the solar cells. While counterdoping has been proposed as a way to reduce cost and complexity, use of ion implantation for counterdoping solar cells is relatively unknown. Counterdoping using ion implantation has only been performed to improve radiation hardening in a solar cell using lithium, not to change carrier type or reduce cost and complexity of solar cell manufacturing. Accordingly, there is a need in the art for an improved method of doping solar cells using counterdoping.

### SUMMARY

The shortcomings of the prior art are overcome by the present disclosure, which describes methods of counterdoping a solar cell, particularly an IBC solar cell. One surface of a solar cell may require portions to be n-doped, while other portions are p-doped. Traditionally, a plurality of lithography and doping steps are required to achieve this desired configuration. In contrast, one lithography step can be eliminated by the use of a blanket doping of one conductivity and a mask patterned counterdoping process of the opposite conductivity. The areas doped during the masked patterned implant receive a sufficient dose so as to completely reverse the effect of the blanket doping and achieve a conductivity that is opposite the blanket doping. In another embodiment, the counterdoping is performed by means of a direct patterning technique, thereby eliminating the remaining lithography step. Various methods of direct counterdoping processes are disclosed.

### BRIEF DESCRIPTION OF THE DRAWINGS

For a better understanding of the present disclosure, reference is made to the accompanying drawings, which are incorporated herein by reference and in which:

FIG. 1 is an embodiment of an exemplary interdigitated back contact solar cell;

FIG. 2 is an embodiment of a solar cell manufacturing process flow;

FIG. 3 is another embodiment of a solar cell manufacturing process flow;

FIG. 4 is an embodiment of counterdoping in a solar cell;

FIG. 5 is a representative coordinate system;

FIG. 6 is a representative ion implanter suitable for use in some embodiments;

FIG. 7 is a third embodiment of a process for counterdoping a solar cell;

FIG. 8 is a fourth embodiment of a process for counterdoping a solar cell;

FIG. 9 is an exemplary solar cell;

FIG. 10 is an exemplary pattern of contacts for an IBC solar cell;

FIG. 11 shows masks that can be employed to create the contacts shown in FIG. 10;

FIG. 12 shows one embodiment of direct patterning;

FIG. 13 shows a second embodiment of direct patterning; and

FIG. 14 shows a third embodiment of direct patterning.

### DETAILED DESCRIPTION

The embodiments of the process described herein may be performed by, for example, a beam-line ion implanter or a plasma doping ion implanter. Such a plasma doping ion implanter may use RF or other plasma generation sources. Other plasma processing equipment or equipment that generates ions also may be used. Thermal or furnace diffusion, pastes on the surface of the solar cell substrate that are heated, epitaxial growth, or laser doping also may be used to perform certain embodiments of the process described herein. Furthermore, while a silicon solar cell is specifically disclosed, other solar cell substrate materials also may benefit from embodiments of the process described herein.

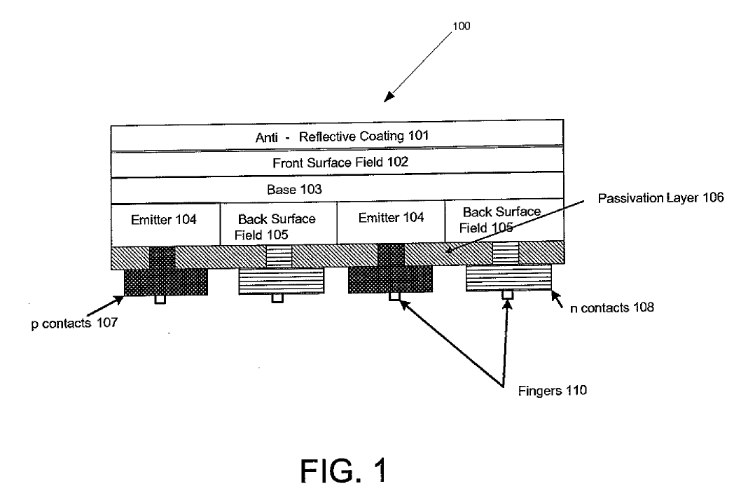

FIG. 1 is an embodiment of an exemplary interdigitated back (or backside) contact (IBC) solar cell. Other embodiments or designs are possible and the embodiments of the process described herein are not solely limited to the IBC solar cell 100 illustrated in FIG. 1. As described above, IBC solar cell 100 includes p contacts 107 and n contacts 108 on the backside of the IBC solar cell 100. At the top of the IBC solar cell 100 is an anti-reflective coating 101. Underneath the anti-reflective coating 101 may be a front surface field 102 and a base 103. Underneath the base 103 are emitters 104 and back surface fields 105. Underneath the emitters 104 and back surface fields 105 is a passivation layer 106. The p contacts 107 and n contacts 108 may go through the passivation layer 106 to contact the emitters 104 and back surface fields 105. Fingers 110, typically made of conductive metal, are attached to the contacts.

Current process flows for IBC solar cells require at least two lithography and diffusion steps on the backside of the solar cell to fabricate the contact (such as p contact 107) and emitter 104 regions.

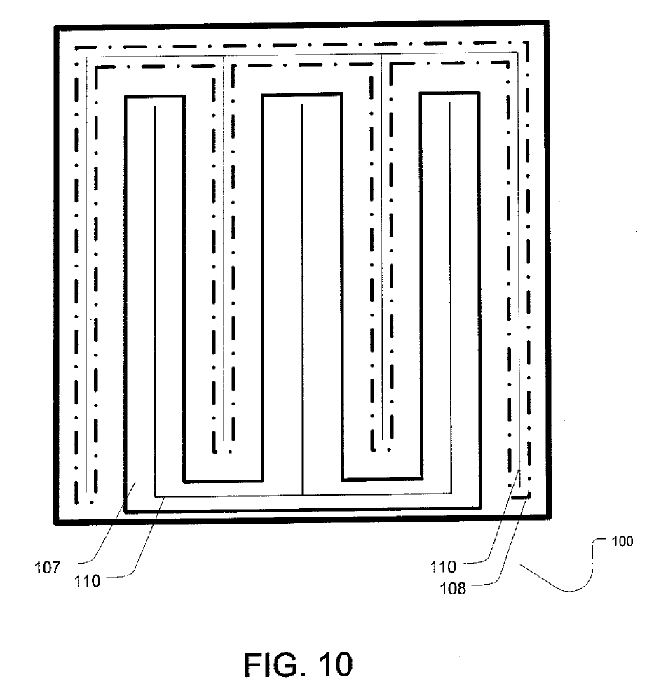

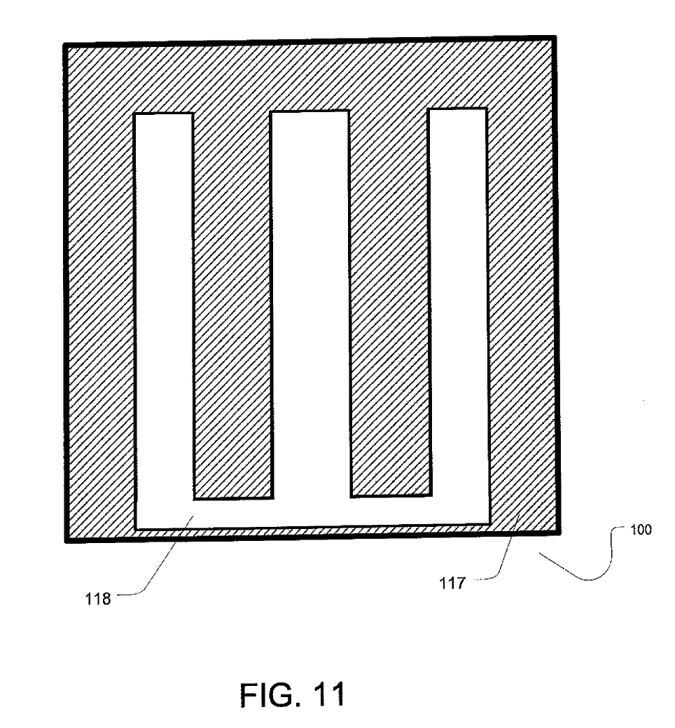

For example, one pattern of contacts is shown in FIG. 10. The emitters, BSF fields and their associated contacts are created in the configuration shown. To create this configuration, often a pattern or mask is used. For example, FIG. 11 shows two masks 117, 118. In one step, mask 117 is applied to the back side of the solar cell 100. A dopant is then introduced into the substrate, such as by diffusion or ion implantation. This pattern or mask is then removed, and a second mask 118 is applied. A second dopant, of opposite conductivity, is then applied, such as by diffusion or ion implantation.

Using counterdoping would allow elimination of at least one of the lithography steps. Counterdoping could eliminate both steps if a non-lithographic technique is used to pattern the dopant in the counterdoping doping process. Elimination of process steps would reduce the manufacturing complexity and manufacturing costs for solar cells.

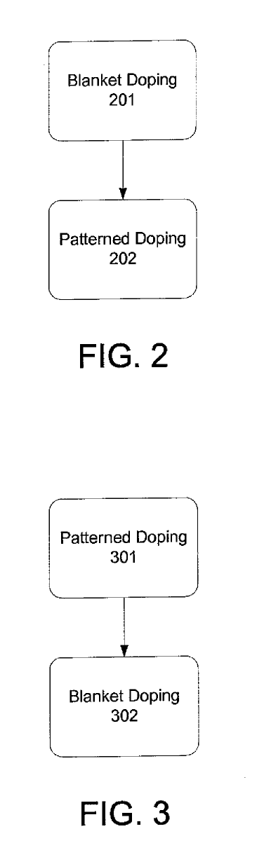

FIG. 2 is an embodiment of a solar cell manufacturing process flow. To perform counterdoping of a solar cell (such as an IBC solar cell), two steps are required: a blanket doping 201 to form one type of semiconductor material. For example, phosphorus may be applied to the entire substrate to form an n-doped region. Following this, a patterned doping 202 in selected regions of the solar cell at a higher dose is performed. This patterned doping 202 is performed using a dopant of opposite conductivity. Thus, if phosphorus is used for the blanket doping, an element from Group III, such as boron, may be used for the pattern doping. Since the area to which the pattern doping is applied has previously been doped, the dosage required must be sufficient to negate the effects of the earlier doping, and then introduce the desired concentration of ions. The result is that the patterned doping creates a region of opposite conductivity to that created by the blanket doping.

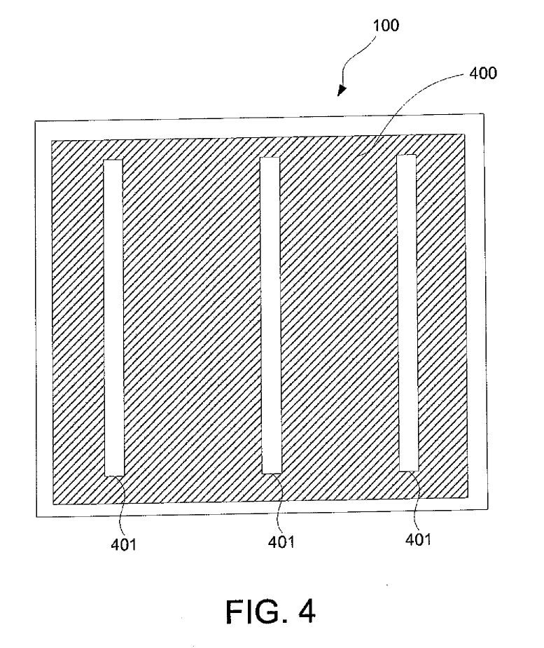

FIG. 3 is another embodiment of a solar cell manufacturing process flow. In this embodiment, the steps performed in FIG. 2 are simply reversed. To perform counterdoping, a patterned doping 301 in selected regions of the solar cell at a higher dose and then a blanket doping 302 to form another type of semiconductor material is performed. The patterned doping 301 is introduced at a sufficient dose such, that the subsequent blanket doping does not change its conductivity.

FIG. 4 is an embodiment of counterdoping. The solar cell 100 includes a blanket doped region 400 and patterned doped regions 401. The blanket doped region 400 and patterned doped regions 401 may be doped in either order or at least partially simultaneously. The blanket doped region 400 and patterned doped region 401 may use either n-type or p-type dopants. However, as stated above, counterdoping requires one region be an n-type dopant and the other region be a p-type dopant. Thus, while the doping with either type of dopant may occur first, different dopants must be used overall. In one particular instance, the blanket doped region 400 is p-type while the patterned doped regions 401 are n-type. Furthermore, the patterned doping must be applied in sufficient amounts to overcome the conductivity produced by the blanket doping. In this example, the n-type dopants are introduced in large enough quantities so that the blanket doped region 400 remains as p-type but the patterned doped regions 401 are n-type.

In the embodiments of the process described herein, the dopants may be, for example, P, As, B, Sb, or Sn. Other dopant species also may be used and this application is not limited merely to the dopants listed.

Blanket doping may be performed in many ways. For example, blanket doping of the region of the solar cell or the entire solar cell may be performed using ion implantation, such as with a beam-line ion implanter or a plasma doping ion implanter. Blanket doping also may be performed using diffusion in a furnace using either at least one gas or at least one paste on the solar cell substrate. Other methods of introducing dopants are also known and are applicable. In all case, blanket doping refers to a doping process where ions are non-discriminately applied to an entire surface of the solar cell.

In contrast to blanket doping, patterned doping means that only select regions of the solar cell are modified. This patterned doping may be performed in multiple ways. In some embodiments, a patterning technique is used to shield (or expose) only certain portions of the substrate. After this pattern is applied, one or more of the processes described above that are used to apply a blanket doping can be performed. In a first embodiment, a mask is used to block areas of the solar cell where counterdoping is not required. The mask may be of various types. For example, a hard mask is one which is applied to and adheres to the substrate. A shadow or proximity mask is one which is placed directly in front of the substrate, and may be reused. Finally, a stencil or projection mask is one in which the mask is placed a distance from the substrate and relies on optics to project a pattern onto the substrate. After the mask is applied, a subsequent diffusion or ion implantation step is performed to introduce ions only to the exposed portions of the substrate. In one further embodiment, ion implantation is then performed, such as using a beam-line ion implanter or a plasma doping ion implanter, and dopants are only implanted through the one or more apertures in the mask. In another instance, the mask is used with a furnace diffusion method.

Patterned doping also may be performed using other methods. As described above, several of these patterning methods shield a portion of the substrate, so that only the exposed portion is doped. For example, photolithography may be used to create a photoresist mask. Other patterning methods are used to expose a portion of the substrate. For example, in one embodiment, a dielectric layer is applied using a blanket doping method. A laser beam may then be used to direct write onto the solar cell to selectively melt the blanket dielectric layer to create a mask. The term “direct write” refers to the process wherein a beam of light or particles, such as a laser or ion beam, is focused with high precision at the substrate. At the areas of incidence, the beam strikes the substrate and causes a specific effect. In the case of an ion beam, the effect may be one of implanting ions in the substrate. In the case of a laser beam, the effect may be to melt or deform the area of incidence.

In another embodiment, material may be printed onto selected regions of the surface of the solar cell. Ion implantation, for example, is then used to introduce dopants through the mask formed by the printed material. Alternatively, the printed material may be used to selectively etch an underlying dielectric, forming a pattern through which dopants can be introduced by diffusion in a furnace. In another embodiment, an ion beam may direct write or be projected through a shadow mask to change the etch characteristics of a blanket dielectric layer. This layer is then etched to expose the substrate only in select regions. In each of these patterning methods, ion implantation or furnace diffusion, for example, is then used to introduce dopants to the desired portion of the substrate.

In other embodiments, direct patterning of the dopant may be performed on the solar cell. The direct patterning form of patterned doping means that only certain regions of the solar cell are doped without the use of a mask or fixed masking layer on the solar cell. In one embodiment, dopants may be implanted with a non-uniform dopant dose using an ion beam. Thus, a first portion of the solar cell is exposed to the ion beam and implanted with a first dose. A second portion of the solar cell also is exposed to the ion beam and implanted with a second dose. This difference in dosage can be achieved in a number of ways.

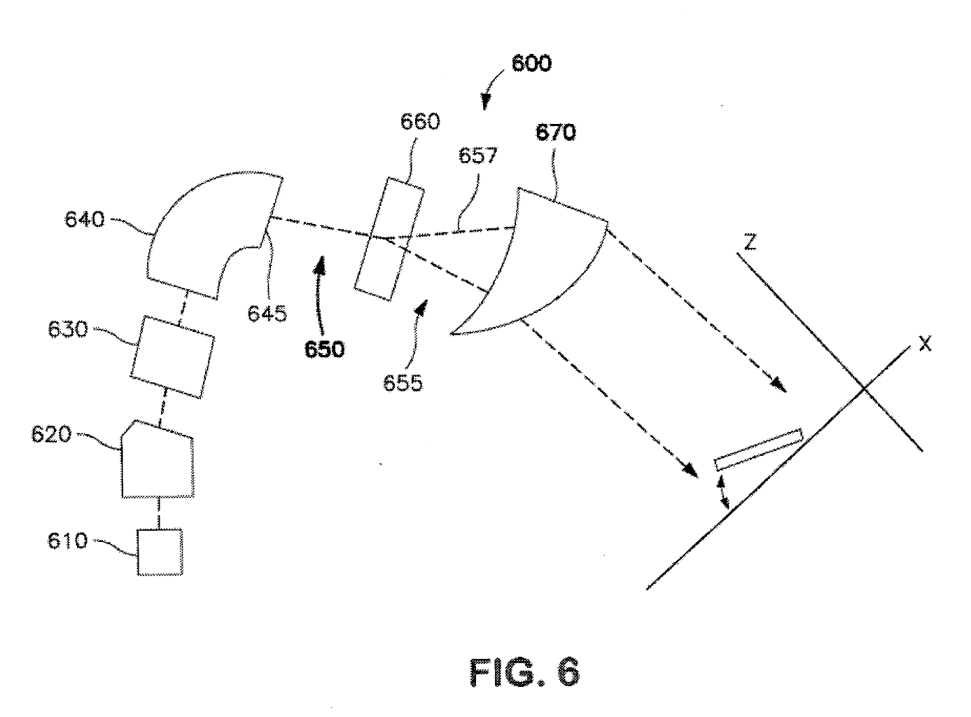

A block diagram of a representative ion implanter 600 is shown in FIG. 6. An ion source 610 generates ions of a desired species, such as phosphorus or boron. A set of electrodes (not shown) is typically used to attract the ions from the ion source. By using an electrical potential of opposite polarity to the ions of interest, the electrodes draw the ions from the ion source, and the ions accelerate through the electrode. These attracted ions are then formed into a beam, which then passes through a source filter 620. The source filter is preferably located near the ion source. The ions within the beam are accelerated/decelerated in column 630 to the desired energy level. A mass analyzer magnet 640, having an aperture 645, is used to remove unwanted components from the ion beam, resulting in an ion beam 650 having the desired energy and mass characteristics passing through resolving aperture 645.

In certain embodiments, the ion beam 650 is a spot beam. In this scenario, the ion beam passes through a scanner 660, preferably an electrostatic scanner, which deflects the ion beam 650 to produce a scanned beam 655 wherein the individual beamlets 657 have trajectories which diverge from scan source 665. In certain embodiments, the scanner 660 comprises separated scan plates in communication with a scan generator. The scan generator creates a scan voltage waveform, such as a sine, sawtooth or triangle waveform having amplitude and frequency components, which is applied to the scan plates. In a preferred embodiment, the scanning waveform is typically very close to being a triangle wave (constant slope), so as to uniformly expose the scanned beam at every position of the substrate for nearly the same amount of time. Deviations from the triangle are used to make the beam uniform. The resultant electric field causes the ion beam to diverge as shown in FIG. 6.

An angle corrector 670 is adapted to deflect the divergent ion beamlets 657 into a set of beamlets having substantially parallel trajectories. Preferably, the angle corrector 670 comprises a magnet coil and magnetic pole pieces that are spaced apart to form a gap, through which the ion beamlets pass. The coil is energized so as to create a magnetic field within the gap, which deflects the ion beamlets in accordance with the strength and direction of the applied magnetic field. The magnetic field is adjusted by varying the current through the magnet coil. Alternatively, other structures, such as parallelizing lenses, can also be utilized to perform this function.

Following the angle corrector 670, the scanned beam is targeted toward the substrate, such as the solar cell to be processed. The scanned beam typically has a height (Y dimension) that is much smaller than its width (X dimension). This height is much smaller than the substrate, thus at any particular time, only a portion of the substrate is exposed to the ion beam. To expose the entire substrate to the ion beam, the substrate must be moved relative to the beam location.

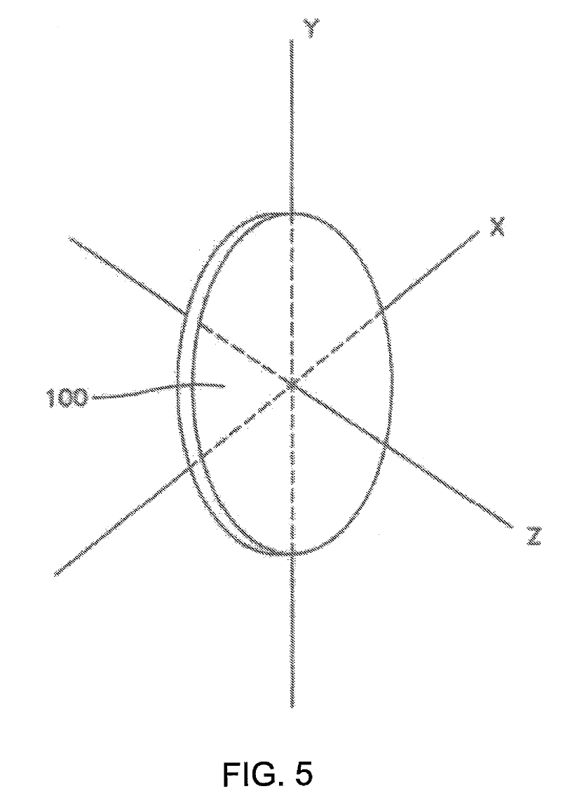

The solar cell is attached to a substrate holder. The substrate holder provides a plurality of degrees of movement. For example, the substrate holder can be moved in the direction orthogonal to the scanned beam. A sample coordinate system in shown in FIG. 5. Assume the beam is in the XZ plane. This beam can be a ribbon beam, or a scanned spot beam. The substrate holder can move in the Y direction. By doing so, the entire surface of the substrate 100 can be exposed to the ion beam, assuming that the substrate 100 has a smaller width than the ion beam (in the X dimension).

In one embodiment, the movement of the substrate holder is modified so as to create longer dwell times at the regions corresponding to the counterdoped regions. In other words, the substrate holder is moved more quickly in the Y direction over those portions of the substrate that are not to be further implanted (i.e. the blanket implant regions). Once the ion beam is positioned over a region that is to be counterdoped, the speed of the substrate holder in the Y direction slows. This slower speed is maintained while the ion beam is over the counterdoped region. Once that region has been fully exposed, the translational speed of the substrate holder increases so as to quickly pass over the subsequent lightly blanket implant regions. This process is repeated until the entire substrate has been implanted.

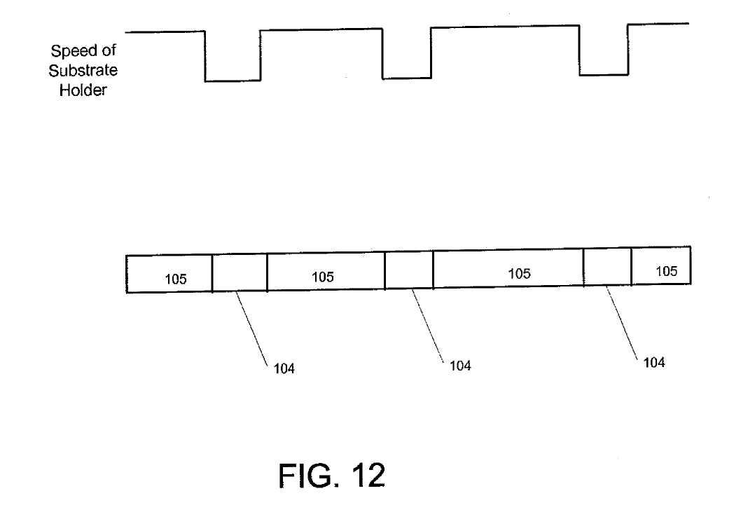

FIG. 12 shows a graph slowing the relative speed of the substrate holder in the Y direction, as a function of the position of the substrate. Note that, in this embodiment, the surface is blanket implanted using an n-type dopant and pattern implanted with a p-type dopant. Thus, when the back surface field region 105 is exposed to the ion beam, the speed is increased. When the emitter region 104 is exposed to the ion beam, the speed is slowed to increase the doping dose.

In the case of a spot beam, a similar technique can be used to move the substrate holder at a variable speed in the Y direction, based on the position on the substrate. If the substrate holder also moves in the X direction to scan across the substrate, the holder can vary the speed in the X direction to achieve the same results described above. In other words, the substrate holder moves quickly in the X direction while exposing emitter regions of the substrate, but slows when exposing the counterdoped regions. Alternatively, the speeds of the substrate holder can be varied in both the X and Y directions if desired.

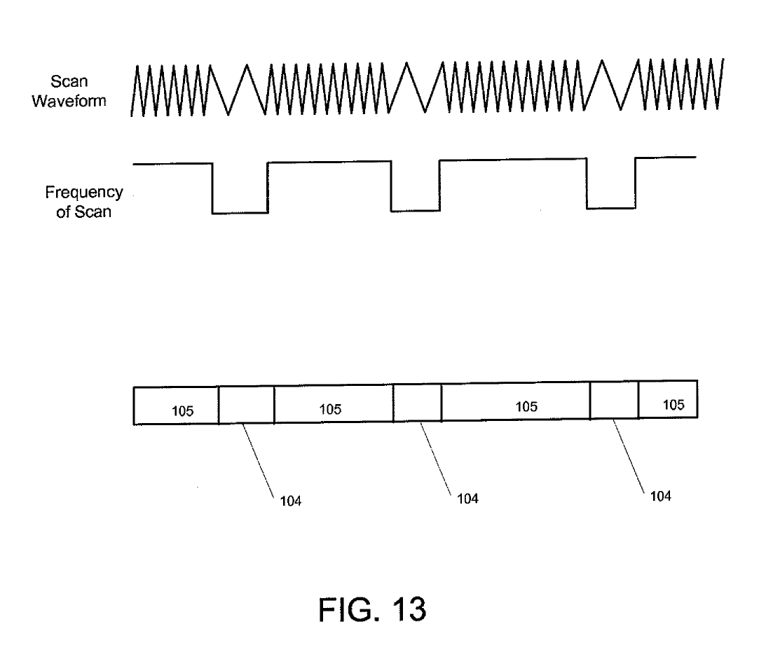

Alternatively, the scanner 660 can be controlled to create a similar result. Assume, in a scanned spot beam implementation, for example, that the substrate holder moves in the Y direction, and that the scanner 660 causes the spot beam to move in the X direction. By varying the frequency of the sawtooth wave used to control the scanner, the rate that the spot beam traverses the substrate can be modified. In one scenario, the frequency of the scanner control signal is increased as the ion beam passes over the exposed emitter region 104, and is slowed when the ion is exposed to the counterdoped region. FIG. 13 shows a graph representing this embodiment. In this way, the dwell time of the back surface field region 105 is less than that of the counterdoped exposed emitter region 104. In another scenario, the waveform of the scanner control signal is modified so that the spot beam is positioned so as not to strike the substrate when passing through the back surface field region 105, and only scans when in the counterdoped exposed emitter region 104. Combining the modification to the scanner input waveform with an alteration to the speed of the substrate holder in the Y direction can also be performed.

While the above methods are mostly concerned with varying the dwell time of the ion beam for various portions of the substrate to vary the doping doses, other methods can be used to create the desired doping pattern. One such technique to create the desired doping pattern is to vary the ion beam current based on the region of the substrate. This can be accomplished in a number of ways.

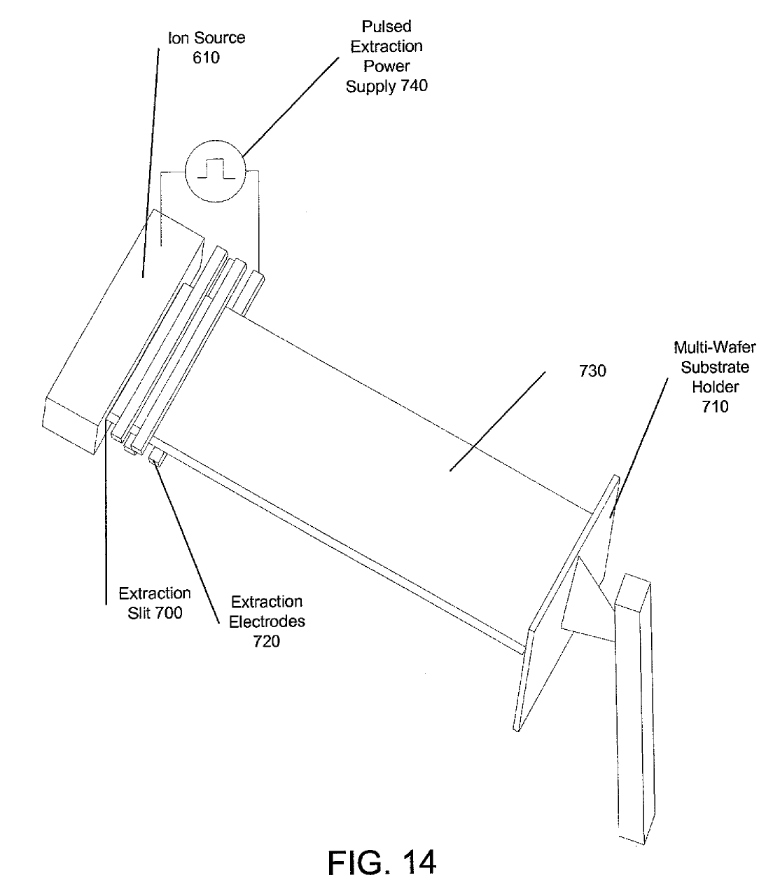

In one embodiment, the ion beam is adjusted by varying the voltage used at the extraction electrodes. FIG. 14 shows a simplified ion implantation system, with only the ion source 610 and the substrate holder 710 shown for clarity. The ion source 610 is used to generate the ion beam 730 to be implanted on the substrate 100. These ions are attracted through the extraction slit 700 of the ion source by one or more sets of extraction electrodes 720. The electrical potential of these electrodes 720 determines the resulting ion beam current. For example, if the electrical potential of the electrodes 720 is very similar to that of the chamber walls of the ion source 610, the flow of ions out of the ion source 610 will be minimal, as there is no attraction to the electrodes. Conversely, if the electrical potential is dramatically different than the chamber walls of the ion source, the ions will be strongly attracted to the electrodes 720. This will result in an ion beam 730 of much higher current. By varying the electrical potential of the electrodes 720 based on the position of the substrate with respect to the ion beam, the desired implantation pattern can be attained.

FIG. 14 shows the use of a pulsed extraction power supply 740 that is activated whenever the counterdoped region 105 of the substrate 100 is in a position where the ion beam will irradiate it. The pulse is then deactivated whenever the ion beam exposes the back surface field 104.

Other components of the ion implantation system can be similarly controlled so as to vary the ion beam current. There are numerous components that can be adjusted in the beam line. For example, a focusing lens element can be pulsed periodically to focus and defocus the beam as the substrate is being scanned to create alternating regions of high and low dopant doses. Such focusing elements may be magnetic (i.e. quadrupole lenses) or electrostatic (i.e. Einzel lenses). The defocusing or focusing of the beam changes the amount of beam that is transmitted into the process chamber (and irradiates the substrate), thus varying the effective beam current incident on the workpiece. In such a scenario, it is possible to dope the entire substrate in a single pass implantation. Similarly, other beamline components that control the transmission of beam through the implanter may be changed. Such components include Acceleration/Deceleration voltages, Magnet settings, and the like.

Direct patterning also may be performed using a blanket layer of dopant-containing paste applied to a solar cell. The paste is selectively melted using a scanned laser beam so that only certain regions of the paste-covered region are doped. This is an example of direct write.

In an alternative embodiment, the paste also may be selectively applied to the solar cell so that only certain paste-covered regions are doped using a furnace. The paste can be selectively applied in many ways. Screen printing, ink jet printing, and extrusion are a few examples. Other methods can also be used and are within the scope of the disclosure.

In another example of direct patterning, the silicon of the solar cell may be selectively melted using a laser while at least partially simultaneously introducing the dopant into the melt from a liquid or gaseous source to perform direct patterning. This is another example of direct write. Only certain regions of the solar cell will be doped in this manner.

FIGS. 3-4 are embodiments of a process for counterdoping a solar cell using mask patterned doping. In the embodiment of FIG. 3, the blanket doping is performed as described above. This blanket doping uniformly introduces ions of a particular conductivity (n or p). In some embodiments, a dose of 2e14 to 1e16 may be used for the blanket doping. After this doping is complete, a mask is applied to or in front of the substrate, and a second blanket doping is performed. This second doping is done using ions of the opposite conductivity as the first doping (e.g. a p-type dopant doping if the first doping was of an n-type dopant). However, due to the presence of the mask, only certain portions of the substrate are doped during the second blanket doping cycle. In some embodiment, a dose of 4e14 to 2e16 may be used for the patterned doping. In another embodiment, shown in FIG. 4, the order of these two processes is reversed, such that the mask is first applied to the substrate and the patterned doping takes place. Afterward, the mask is removed from the substrate, and a blanket doping is performed. This use of this technique in these embodiments eliminates the need for one of the lithography steps that are used in current solar cell manufacturing processes.

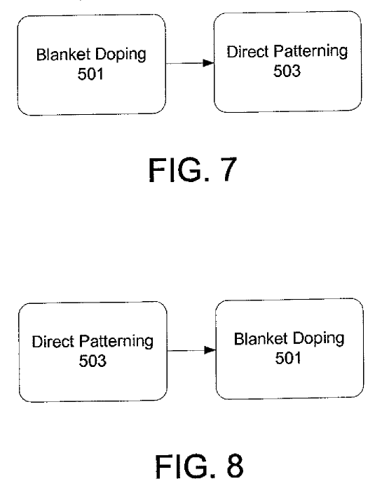

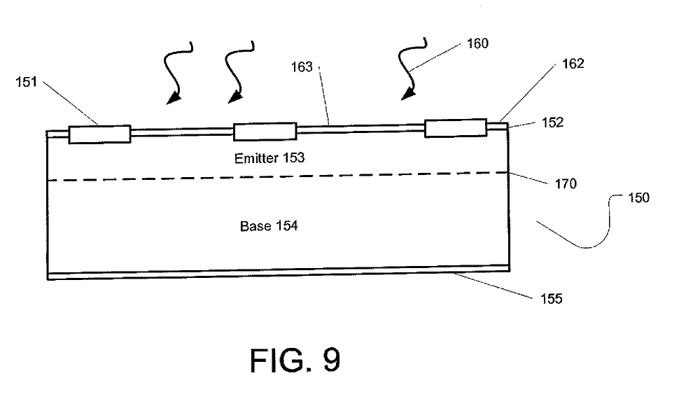

FIGS. 7-8 are embodiments of a process for counterdoping a solar cell using direct patterning. In the embodiment shown in FIG. 7, a blanket doping, as described above, is applied to the substrate first. After this is completed, a second doping, using one of the direct patterning technique described above.

N-type and p-type regions on the backside of a solar cell may have different depth profiles to ensure proper operation of the solar cell. The counterdoping profile may need to extend beyond the doped region into the bulk of the solar cell material. To prevent minority carriers from being attracted to the surface of the solar cell or from being trapped in local potential wells, the doping levels between the blanket and counterdoping profile may need to decrease monotonically away from the surface of the solar cell. Ion implantation using a beam-line or plasma doping ion implanter allows both profile requirements to be met. If furnace diffusion is used as a process step, the profiles can be achieved through tailoring the thermal process. For example, a two-step diffusion process may be used. This two-step diffusion process uses higher and lower temperatures to activate and drive-in the dopants to different depths. In another example, a thermal anneal process is used on the first dopant and a rapid thermal processing (RTP) anneal is performed on the second dopant. In yet another example, the two doping steps are performed at different temperatures.

The terms and expressions which have been employed herein are used as terms of description and not of limitation, and there is no intention in the use of such terms and expressions of excluding any equivalents of the features shown and described (or portions thereof). It is also recognized that various modifications are possible within the scope of the claims. Other modifications, variations, and alternatives are also possible. Accordingly, the foregoing description is by way of example only and is not intended as limiting.

What is claimed is:

1. A solar cell comprising:
a substrate having an illuminated surface and a non-illuminated surface, wherein light impinges said illuminated surface;
an anti-reflective coating on said illuminated surface of said substrate;
a front surface field under said anti-reflective coating;
a plurality of n-type doped regions on said non-illuminated surface having an n-type dopant concentration;
a plurality of p-type doped regions on said non-illuminated surface having a p-type dopant concentration and said n-type dopant concentration, wherein said p-type dopant concentration is larger than said n-type dopant concentration; and
a plurality of contacts disposed on said plurality of p-type doped regions and said plurality of n-type doped regions.

2. The solar cell of claim 1, wherein one of said plurality of p-type doped regions is disposed between two of said plurality of n-type doped regions.

3. The solar cell of claim 1, wherein said plurality of p-type doped regions and said plurality of n-type doped regions alternate across said non-illuminated surface.

4. The solar cell of claim 1, further comprising a passivation layer on said non-illuminated surface.

5. The solar cell of claim 1, wherein said plurality of p-type regions extends deeper into said substrate than said plurality of n-type doped regions.

6. A solar cell comprising:
a substrate having an illuminated surface and a non-illuminated surface, wherein light impinges said illuminated surface;
an anti-reflective coating on said illuminated surface of said substrate;
a front surface field under said anti-reflective coating;
a plurality of p-type doped regions on said non-illuminated surface having a p-type dopant concentration;
a plurality of n-type doped regions on said non-illuminated surface having an n-type dopant concentration and said p-type dopant concentration, wherein said n-type dopant concentration is larger than said p-type dopant concentration; and
a plurality of contacts disposed on said plurality of p-type doped regions and said plurality of n-type doped regions.

7. The solar cell of claim 6, wherein one of said plurality of p-type doped regions is disposed between two of said plurality of n-type doped regions.

8. The solar cell of claim 6, wherein said plurality of p-type doped regions and said plurality of n-type doped regions alternate across said non-illuminated surface.

9. The solar cell of claim 6, further comprising a passivation layer on said non-illuminated surface.

10. The solar cell of claim 6, wherein said plurality of n-type regions extends deeper into said substrate than said plurality of p-type doped regions.

11. A solar cell comprising:
a substrate having an illuminated surface and a non-illuminated surface, wherein light impinges said illuminated surface;
a plurality of first doped regions on said non-illuminated surface having a first dopant concentration of a first dopant type;
a plurality of second doped regions on said non-illuminated surface having said first dopant concentration and a second dopant concentration of a second dopant type, said second dopant concentration being larger than said first dopant concentration; and
a plurality of contacts disposed on said plurality of first doped regions and said plurality of second doped regions.

12. The solar cell of claim 11, wherein one of said plurality of second doped regions is disposed between two of said plurality of first doped regions.

13. The solar cell of claim 11, wherein said plurality of first doped regions and said plurality of second doped regions alternate across said non-illuminated surface.

14. The solar cell of claim 11, further comprising an anti-reflective coating on said illuminated surface.

15. The solar cell of claim 14, further comprising a front surface field under said anti-reflective coating.

16. The solar cell of claim 11, wherein said first dopant type is p-type and said second dopant type is n-type.

17. The solar cell of claim 11, wherein said first dopant type is n-type and said second dopant type is p-type.

18. The solar cell of claim 11, further comprising a passivation layer on said non-illuminated surface.

19. The solar cell of claim 11, wherein said plurality of second doped regions extends deeper into said substrate than said plurality of first doped regions.
